(19) United States
(12) Patent Application Publication
(10) Pub. No.: US 2013/0043772 A1
(43) Pub. Date: Feb. 21, 2013

(54) CASE FOR ULTRASONIC SENSOR AND ULTRASONIC SENSOR USING THE SAME

(71) Applicants: Boum Seock Kim, Gyunggi-do (KR); Eun Tae Park, Gyunggi-do (KR)

(72) Inventors: Boum Seock Kim, Gyunggi-do (KR); Eun Tae Park, Gyunggi-do (KR)

(73) Assignee: SAMSUNG ELECTRO-MECHANICS CO., LTD., Gyunggi-do (KR)

(21) Appl. No.: 13/311,872

(22) Filed: Dec. 6, 2011

(30) Foreign Application Priority Data
Aug. 19, 2011 (KR) 1020110082971

(51) Int. Cl. H01L 41/053; B65D 85/00

(52) U.S. Cl. 310/348; 206/722

(57) ABSTRACT

Disclosed herein are a case for an ultrasonic sensor and an ultrasonic sensor using the same. The case for an ultrasonic sensor has a cylindrical shape and includes a disposition area of a piezoelectric element and a first groove formed in an inner side bottom surface thereof, wherein the first groove is formed along an edge of the disposition area of the piezoelectric element.

### CROSS REFERENCE TO RELATED APPLICATION

This application claims the benefit of Korean Patent Application No. 10-2011-0082971, filed on Aug. 19, 2011, entitled “Case for Ultrasonic Sensor and Ultrasonic Sensor Using the Same”, which is hereby incorporated by reference in its entirety into this application.

### BACKGROUND OF THE INVENTION

1. Technical Field

The present invention relates to a case for an ultrasonic sensor and an ultrasonic sensor using the same.

2. Description of the Related Art

An ultrasonic sensor is a sensor using the principle in which as a voltage is applied to a piezoelectric material, the piezoelectric material is periodically deformed to thereby generate an ultrasonic wave and an ultrasonic wave returned by reflection of the generated ultrasonic wave on an obstacle is re-measured to thereby calculate an actual distance.

The above-mentioned ultrasonic sensor has been used in various fields including a rear stabilization device for a vehicle that may sense an obstacle at the time of backing of a vehicle to thereby prevent an accident.

The above-mentioned ultrasonic sensor is mounted with a piezoelectric element generating an ultrasonic wave. Vibration of this piezoelectric element is transferred outside a case, such that the above-mentioned ultrasonic sensor serves as a sensor.

In this situation, internal vibration corresponding to noise other than vibration required for sensing an object is generated, which causes accuracy of an object detection result to be lowered.

Meanwhile, the ultrasonic sensor uses an adhesive in order to mount a piezoelectric element in a case. In this situation, when an adhesive more than a required amount is used, the adhesive often overflows to sides of the piezoelectric element and moves from the sides of the piezoelectric element up to an upper surface thereof.

This reduces the capability of the piezoelectric element to control vibration force to thereby decay vibration force for recognizing an object and increase a time required to decay vibration corresponding to noise.

### SUMMARY OF THE INVENTION

The present invention has been made in an effort to provide a case for an ultrasonic sensor in which a piezoelectric element may not be affected by an adhesive when the piezoelectric element is adhered to the case, and an ultrasonic sensor using the same.

Further, the present invention has been made in an effort to provide a case for an ultrasonic sensor in which a substrate may be more easily mounted in the case, and an ultrasonic sensor using the same.

According to a first preferred embodiment of the present invention, there is provided a case for an ultrasonic sensor having a cylindrical shape and comprising a disposition area of a piezoelectric element and a first groove formed in an inner side bottom surface thereof, wherein the first groove is formed along an edge of the disposition area of the piezoelectric element.

The disposition area of the piezoelectric element may have a size corresponding to that of the piezoelectric element.

The case may further include a spaced space formed between the first groove and a sidewall of the case and having the same height as that of the disposition area of the piezoelectric element.

The case may further include a second groove formed in an inner side wall surface thereof in a thickness direction thereof, wherein the second groove is formed from a point spaced apart from the bottom surface of the case so as to correspond to a component mounting area up to a top surface thereof.

The second groove may be formed as a pair of grooves, and each of the two grooves may be formed so as to face each other and be spaced apart from each other in both sides of the inner to side wall surface.

According to a second preferred embodiment of the present invention, there is provided an ultrasonic sensor including: a case having a cylindrical shape and including a disposition area of a piezoelectric element and a first groove formed in an inner side bottom surface thereof, the first groove being formed along an edge of the disposition area of the piezoelectric element; the piezoelectric element mounted in the disposition area of the piezoelectric element; and an adhesive mounting the piezoelectric element on the case.

The adhesive may be epoxy.

The disposition area of the piezoelectric element may have a size corresponding to that of the piezoelectric element.

The case may further include a spaced space formed between the first groove and a sidewall of the case and having the same height as that of the disposition area of the piezoelectric element.

The case may further include a second groove formed in an inner side wall surface thereof in a thickness direction thereof, wherein the second groove is formed from a point spaced apart from the bottom surface of the case so as to correspond to a component mounting area up to a top surface thereof.

The second groove may be formed as a pair of grooves, and each of the two grooves may be formed so as to face each other and be spaced apart from each other in both sides of the inner side wall surface.

### BRIEF DESCRIPTION OF THE DRAWINGS

FIG. 1 is a cross-sectional view showing a configuration of a case for an ultrasonic sensor according to a preferred embodiment of the present invention;

FIG. 2 is a plan view showing the configuration of the case for an ultrasonic sensor according to the preferred embodiment of the present invention;

FIG. 3 is a plan view showing a configuration of an ultrasonic sensor according to the preferred embodiment of the present invention;

FIG. 4 is a view describing an adhering method of a piezoelectric element according to the preferred embodiment of the present invention in detail; and

FIG. 5 is a view showing a configuration of a second groove according to the preferred embodiment of the present invention in detail.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

Case for Ultrasonic Sensor

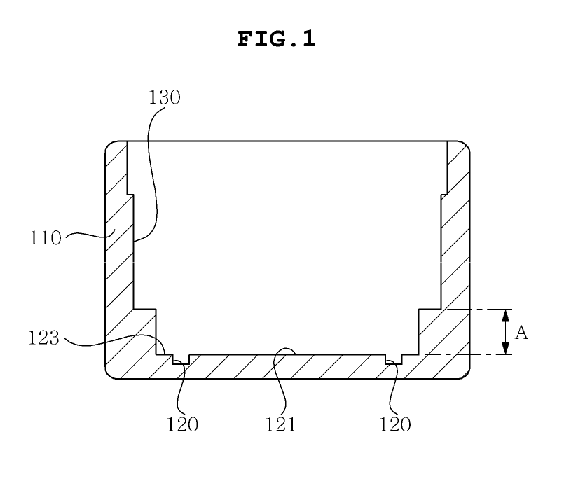

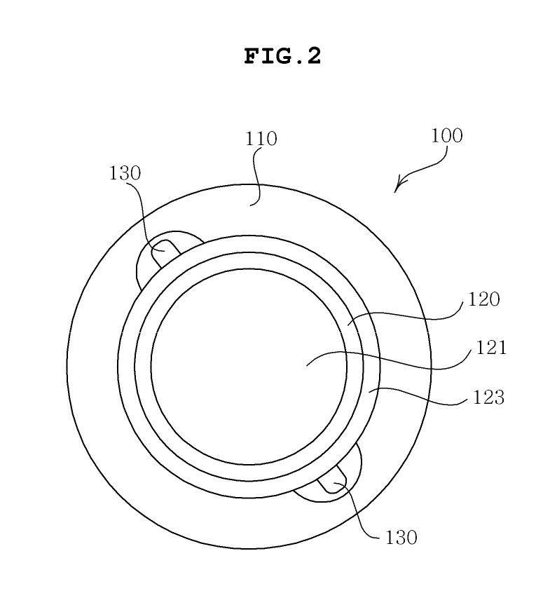

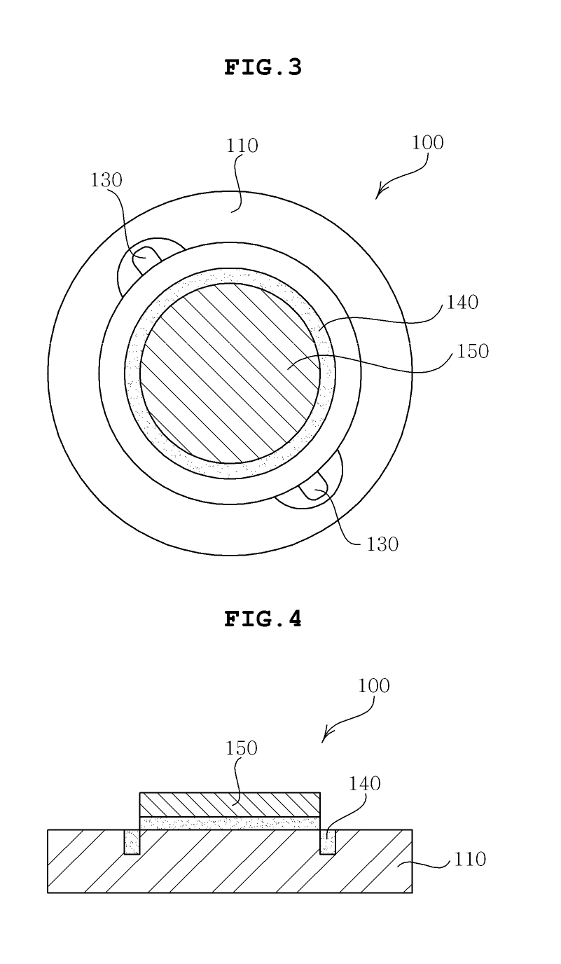

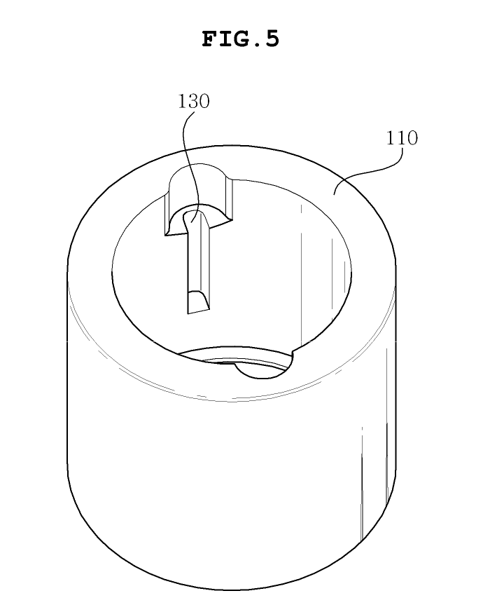

FIG. 1 is a cross-sectional view showing a configuration of a case for an ultrasonic sensor according to a preferred embodiment of the present invention; FIG. 2 is a plan view showing the configuration of the case for an ultrasonic sensor according to the preferred embodiment of the present invention; FIG. 3 is a plan view showing a configuration of an ultrasonic sensor according to the preferred embodiment of the present invention; FIG. 4 is a view describing an adhering method of a piezoelectric element according to the preferred embodiment of the present invention in detail; and FIG. 5 is a view showing a configuration of a second groove according to the preferred embodiment of the present invention in detail.

As shown in FIG. 1, a case 110 for an ultrasonic sensor has a cylindrical shape and may include a disposition area 121 of a piezoelectric element and a first groove 120 formed in an inner side bottom surface thereof, wherein the first groove 120 is formed along an edge of the disposition area 121 of the piezoelectric element.

Here, the disposition area 121 of the piezoelectric element has a size corresponding to that of the piezoelectric element.

That is, as shown in FIG. 2, the disposition area 121 of the piezoelectric element has the same size as a size in which a shape (for example, a circular shape) of the piezoelectric element is reflected. Here, the term ‘same’ means substantially the same plane size in consideration of a manufacturing error, a measuring error, or the like, in a thickness of accurately the same dimension in a mathematical meaning.

In addition, the case 110 for an ultrasonic sensor includes a spaced space 123 formed between the first groove 120 and a sidewall of the case 110 and having the same height as that of the disposition area 121 of the piezoelectric element.

As shown in FIGS. 3 and 4, when a piezoelectric element 150 is adhered to a bottom surface of the case 110 by an adhesive, the above-mentioned first groove 120 may allow an overflowing adhesive to flow therein.

Therefore, when the piezoelectric element 150 is adhered to the bottom surface of the case 110, even though an amount of adhesive is large, a problem that the adhesive rises along a side of the piezoelectric element 150 to thereby cover an upper surface of the piezoelectric element 150 may be prevented beforehand.

The adhesive covering the side and the upper surface of the piezoelectric element 150 reduces the capability of the piezoelectric element 150 to control vibration force to thereby decay vibration force for recognizing an object and to increase a decay time of vibration corresponding to noise. The above-mentioned problem may be prevented by the first groove 120 according to the preferred embodiment of the present invention.

For example, the decay time is reduced by about 10% or more since the adhesive flows in the first groove 120. Here, the decay time means a time required to decay vibration generated by transmitting an ultrasonic wave.

In addition, as shown in FIG. 5, the case 110 for an ultrasonic sensor may further include a second groove 130 formed in an inner side wall surface thereof in a thickness direction thereof, wherein the second groove 130 is formed from a point spaced apart (See A of FIG. 1) from the bottom surface of the case 110 so as to correspond to a component mounting area up to a top surface thereof.

Here, the second groove 130 is formed as a pair of grooves, and each of the two grooves may be formed so as to face each other and be spaced apart from each other in both sides of the inner side wall surface.

The above-mentioned second grooves 130 are to insert electric wires connected to a substrate (not shown) thereinto for electric connection. When the substrate is mounted in the case 110, the electric wires are inserted into the second grooves formed in both sides of the case 110.

Therefore, a process of mounting the substrate in the case 110 may be easily performed.

In addition, A of FIG. 1 is a space considering the piezoelectric element, a sound absorbing material, or the like, mounted in the case before the substrate is mounted therein.

Ultrasonic Sensor

As shown in FIGS. 1 and 3, an ultrasonic sensor 100 may include the case 110 having a cylindrical shape and including the disposition area 121 of the piezoelectric element and the first groove 120 formed in the inner side bottom surface thereof, the first groove 120 being formed along the edge of the disposition area of the piezoelectric element; the piezoelectric element 150 mounted in the disposition area of the piezoelectric element; and the adhesive 140 mounting the piezoelectric element 150 to the case 110.

Here, the adhesive 140 may be epoxy but is not limited thereto.

In addition, the disposition area 121 of the piezoelectric element may have a size corresponding to that of the piezoelectric element 150.

That is, as shown in FIG. 2, the disposition area 121 of the piezoelectric element has the same size as a size at which a shape (for example, a circular shape) of the piezoelectric element is reflected. Here, the term ‘same’ means substantially the same plane size in consideration of a manufacturing error, a measuring error, or the like, in a thickness of accurately the same dimension in a mathematical meaning.

In addition, the case 110 for an ultrasonic sensor includes a spaced space 123 formed between the first groove 120 and the sidewall of the case 110 and having the same height as that of the disposition area 121 of the piezoelectric element.

As shown in FIGS. 3 and 4, when a piezoelectric element 150 is adhered to a bottom surface of the case 110 by an adhesive, the above-mentioned first groove 120 may allow an overflowing adhesive to flow therein.

Therefore, when the piezoelectric element 150 is adhered to the bottom surface of the case 110, even though an amount of adhesive is large, a problem that the adhesive rises along a side of the piezoelectric element 150 to thereby cover an upper surface of the piezoelectric element 150 may be prevented beforehand.

The adhesive covering the side and the upper surface of the piezoelectric element 150 reduces the capability of the piezoelectric element 150 to control vibration force to thereby decay vibration force for recognizing an object and increase a decay time of vibration corresponding to noise. The above-mentioned problem may be prevented by the first groove 120 according to the preferred embodiment of the present invention.

In addition, as shown in FIG. 5, the case 110 for an ultrasonic sensor may further include a second groove 130 formed in an inner side wall surface thereof in a thickness direction thereof, wherein the second groove 130 is formed from a point spaced apart (See A of FIG. 1) from the bottom surface of the case 110 so as to correspond to a component mounting area up to a top surface thereof.

Here, the second groove 130 is formed as a pair of grooves, and each of the two grooves may be formed so as to face each other and be spaced apart from each other in both sides of the inner side wall surface.

With the case for an ultrasonic sensor and the ultrasonic sensor using the same according to the preferred embodiments of the present invention, since the groove is formed in the vicinity of a mounting area of the piezoelectric element in the inner side bottom surface of the case, when the piezoelectric element is adhered to the case, an overflowing adhesive flows in the groove, thereby making it possible not to affect the piezoelectric element.

In addition, according to the preferred embodiments of the present invention, the groove is formed in the inner side wall surface of the case, and the electric wire connected to the substrate is inserted into the groove at the time of mounting of the substrate in the case, thereby making it possible to easily mount the component including the substrate.

Although the preferred embodiments of the present invention have been disclosed for illustrative purposes, they are for specifically explaining the present invention and thus a case for an ultrasonic sensor and an ultrasonic sensor using the same according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. A case for an ultrasonic sensor having a cylindrical shape and comprising a disposition area of a piezoelectric element and a first groove formed in an inner side bottom surface thereof, wherein the first groove is formed along an edge of the disposition area of the piezoelectric element.

2. The case as set forth in claim 1, wherein the disposition area of the piezoelectric element has a size corresponding to that of the piezoelectric element.

3. The case as set forth in claim 1, further comprising a spaced space formed between the first groove and a sidewall of the case and having the same height as that of the disposition area of the piezoelectric element.

4. The case as set forth in claim 1, further comprising a second groove formed in an inner side wall surface thereof in a thickness direction thereof, wherein the second groove is formed from a point spaced apart from the bottom surface of the case so as to correspond to a component mounting area up to a top surface thereof.

5. The case as set forth in claim 4, wherein the second groove is formed as a pair of grooves, and each of the two grooves is formed so as to face each other and be spaced apart from each other in both sides of the inner side wall surface.

6. An ultrasonic sensor comprising:
a case having a cylindrical shape and including a disposition area of a piezoelectric element and a first groove formed in an inner side bottom surface thereof, the first groove being formed along an edge of the disposition area of the piezoelectric element;
the piezoelectric element mounted in the disposition area of the piezoelectric element; and
an adhesive mounting the piezoelectric element on the case.

7. The ultrasonic sensor as set forth in claim 6, wherein the adhesive is epoxy.

8. The ultrasonic sensor as set forth in claim 6, wherein the disposition area of the piezoelectric element has a size corresponding to that of the piezoelectric element.

9. The ultrasonic sensor as set forth in claim 6, wherein the case further includes a spaced space formed between the first groove and a sidewall of the case and having the same height as that of the disposition area of the piezoelectric element.

10. The ultrasonic sensor as set forth in claim 6, wherein the case further includes a second groove formed in an inner side wall surface thereof in a thickness direction thereof, the second groove being formed from a point spaced apart from the bottom surface of the case so as to correspond to a component mounting area up to a top surface thereof.

11. The ultrasonic sensor as set forth in claim 10, wherein the second groove is formed as a pair of grooves, and each of the two grooves is formed so as to face each other and be spaced apart from each other in both sides of the inner side wall surface.
